(19) United States
(12) Patent Application Publication
(10) Pub. No.: US 2011/0147809 A1
(43) Pub. Date: Jun. 23, 2011

(54) FORMING A CARBON CONTAINING LAYER TO FACILITATE SILICIDE STABILITY IN A SILICON GERMANIUM MATERIAL

(76) Inventors: Bin Yang, Ossining, NY (US); Devendra Sadana, Pleasantville, NY (US); Christian Lavoie, Pleasantville, NY (US); Ahmet Ozcan, Pleasantville, NY (US)

(21) Appl. No.: 12/644,092

(22) Filed: Dec. 22, 2009

(51) Int. Cl. H01L 29/78; H01L 21/20; H01L 21/336

(52) U.S. Cl. 257/288; 438/478; 438/285; 257/E21.09; 257/E21.409; 257/E29.255

(57) ABSTRACT

A method includes forming a silicon germanium layer, forming a layer comprising carbon and silicon on a top surface of the silicon germanium layer, forming a metal layer above the layer comprising carbon and silicon, and performing a thermal treatment to convert at least the layer comprising carbon and silicon to form a metal silicide layer.

### CROSS-REFERENCE TO RELATED APPLICATIONS

Not applicable.

### BACKGROUND

The present subject matter relates generally to semiconductor device manufacturing and, more particularly, to forming a carbon containing layer to facilitate silicide stability in a silicon germanium material.

The fabrication of complex integrated circuits involves the fabrication of a large number of transistor elements, which are used in logic circuits as switching devices. Generally, various process technologies are currently practiced for complex circuitry, such as microprocessors, storage chips, and the like. One process technology currently used is complimentary metal oxide silicon (CMOS) technology, which provides benefits in terms of operating speed, power consumption, and/or cost efficiency. In CMOS circuits, complementary transistors (e.g., p-channel transistors and n-channel transistors) are used for forming circuit elements, such as inverters and other logic gates to design complex circuit assemblies, such as CPUs, storage chips, and the like.

During the fabrication of complex integrated circuits using CMOS technology, millions of transistors are formed on a substrate including a crystalline semi-conductor layer. A transistor includes PN-junctions that are formed by an interface of highly doped drain and source regions with an inversely doped channel region disposed between the drain region and the source regions. The conductivity of the channel region, i.e., the drive current capability of the conductive channel, is controlled by a gate electrode formed in the vicinity of the channel region and separated therefrom by a thin insulating layer. A conductive channel is formed when an appropriate control voltage is applied to the gate electrode. The conductivity of the channel region depends on the dopant concentration, the mobility of the majority charge carriers, and—for a given extension of the channel region in the transistor width direction—on the distance between the source and drain regions, which is also referred to as channel length.

Hence, the overall conductivity of the channel region substantially determines an aspect of the performance of the MOS transistors. By reducing the channel length, and accordingly, the channel resistivity, an increase in the operating speed of the integrated circuits may be achieved.

The continuing shrinkage of the transistor dimensions raises issues that tend to offset some of the advantages gained by the reduced channel length. For example, highly sophisticated vertical and lateral dopant profiles may be required in the drain and source regions to provide low sheet and contact resistivity in combination with a desired channel controllability. Moreover, the gate dielectric material may also be adapted to the reduced channel length in order to maintain the required channel controllability. However, some mechanisms for obtaining a high channel controllability may also have a negative influence on the charge carrier mobility in the channel region of the transistor, thereby partially offsetting the advantages gained by the reduction of the channel length.

The continuous size reduction of the critical dimensions, i.e., the gate length of the transistors, necessitates the adaptation of current process techniques and possibly the development of new process techniques. One technique for enhancing the channel conductivity of the transistor elements involves increasing the charge carrier mobility in the channel region for a given channel length, thereby offering the potential for achieving a performance improvement that is comparable with the advance to a future technology node while avoiding or at least postponing many of the process adaptations associated with device scaling.

One efficient mechanism for increasing the charge carrier mobility is to modify the lattice structure in the channel region, for instance by creating tensile or compressive stress in the vicinity of the channel region so as to produce a corresponding strain in the channel region, which results in a modified mobility for electrons and holes, respectively. For example, creating tensile strain in the channel region for a standard crystallographic configuration of the active silicon material increases the mobility of electrons, which, in turn, may directly translate into a corresponding increase in the conductivity. On the other hand, compressive strain in the channel region may increase the mobility of holes, thereby providing the potential for enhancing the performance of p-type transistors.

The introduction of stress or strain engineering into integrated circuit fabrication is a promising approach for future device generations. Strained silicon may be considered as a “new” type of semiconductor material that enables the fabrication of fast powerful semiconductor devices without requiring expensive semi-conductor materials and also allows the use of many of the well-established current manufacturing techniques.

One technique for inducing stress in the channel region involves introducing, for instance, a silicon germanium layer next to the channel region so as to induce a compressive stress that may result in a corresponding strain. The transistor performance of p-channel transistors may be considerably enhanced by the introduction of stress-creating layers next to the channel region. For this purpose a strained silicon germanium layer may be formed in the drain and source regions of the transistors. The compressively strained drain and source regions create uni-axial strain in the adjacent silicon channel region. When forming the Si/Ge layer, the drain and source regions of the PMOS transistors are selectively recessed, while the NMOS transistors are masked. Subsequently, the silicon germanium layer is selectively formed by epitaxial growth. For generating a tensile strain in the silicon channel region, silicon carbon may be used instead of Si/Ge.

Metal silicide regions may be formed on the upper surfaces of the source/drain regions and/or the gate electrode to reduce the contact resistance. Such metal silicide regions may, at least in some cases, assist in increasing device performance in that they tend to reduce various resistances encountered in operating the transistor. Nickel silicide has been widely used for advance CMOS devices as the contact material. However, nickel silicide suffers from poor thermal stability. To further enhance the hole mobility and boost device performance by increasing the compressive strain generated in the channel, it has been proposed to increase the germanium concentration. The thermal stability of the Ni (or its alloy) germano-silicide becomes even worse with higher Ge concentration. Nickel germano silicide encroachment on PFET devices also degrades yield.

This section of this document is intended to introduce various aspects of art that may be related to various aspects of the disclosed subject matter described and/or claimed below. This section provides background information to facilitate a better understanding of the various aspects of the disclosed subject matter. It should be understood that the statements in this section of this document are to be read in this light, and not as admissions of prior art. The disclosed subject matter is directed to overcoming, or at least reducing the effects of, one or more of the problems set forth above.

### BRIEF SUMMARY

The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

One aspect of the disclosed subject matter is seen in a method for forming a silicide. The method includes forming a silicon germanium layer, forming a layer comprising carbon and silicon on a top surface of the silicon germanium layer, forming a metal layer above the layer comprising carbon and silicon, and performing a thermal treatment to convert at least the layer comprising carbon and silicon to form a metal silicide layer.

Another aspect of the disclosed subject matter is seen in a method for forming a transistor. The method includes forming a gate electrode structure above a semiconductor layer, forming a recess in the semiconductor layer adjacent the gate electrode, forming a silicon germanium material in the recess, forming a layer comprising carbon and silicon on a top surface of the silicon germanium material, forming a metal layer above the layer comprising carbon and silicon, and performing a thermal treatment to convert at least the layer comprising carbon and silicon to form a metal silicide layer.

Yet another aspect of the disclosed subject matter is seen in a semiconductor device including a silicon germanium layer and a silicide layer comprising a metal, silicon, and carbon formed on the silicon germanium layer to define an interface therewith.

### BRIEF DESCRIPTION OF THE SEVERAL VIEWS OF THE DRAWINGS

The disclosed subject matter will hereafter be described with reference to the accompanying drawings, wherein like reference numerals denote like elements, and:

FIG. 1 is a cross section of a semiconductor device including a silicon carbon layer formed above a silicon germanium material in accordance with one aspect of the present subject matter;

FIG. 2 is a cross section of the device of FIG. 1 with a metal layer formed above the silicon carbon layer; and

FIG. 3 is a cross section of the device of FIG. 2 after a thermal treatment to form a silicide layer.

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the spirit and scope of the disclosed subject matter as defined by the appended claims.

### DETAILED DESCRIPTION

One or more specific embodiments of the disclosed subject matter will be described below. It is specifically intended that the disclosed subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the disclosed subject matter unless explicitly indicated as being “critical” or “essential.”

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

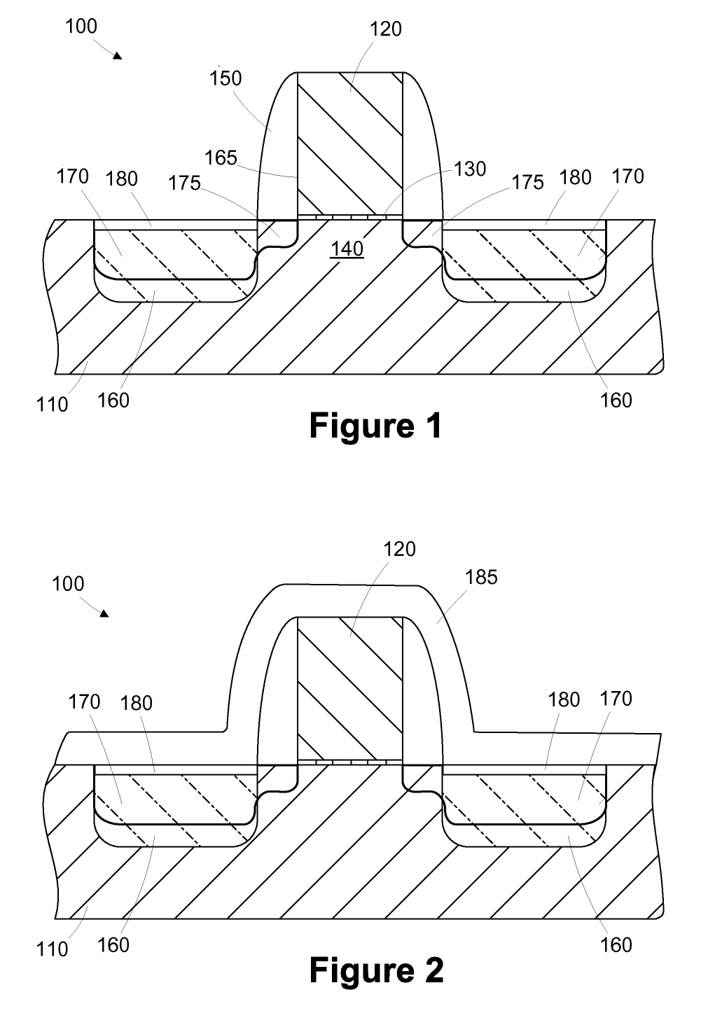

Referring now to the drawings wherein like reference numbers correspond to similar components throughout the several views and, specifically, referring to FIGS. 1-3, the disclosed subject matter shall be described in the context a semi-conductor device 100. FIG. 1 shows a cross-sectional view of the semiconductor device 100. The semiconductor device 100 includes a semiconductor layer 110 of a first semiconductor material in and/or on which circuit elements, such as transistors, capacitors, resistors, and the like may be formed. The semiconductor layer 110 may be provided on a substrate (not shown), e.g. on a bulk semiconductor substrate or a semiconductor-on-insulator (SOI) substrate, wherein the semiconductor layer 110 may be formed on a buried insulation layer. The semiconductor layer 110 may be a silicon-based crystalline semiconductor layer comprising silicon with a concentration of at least 50%. The semiconductor layer 110 may represent a doped silicon layer as is typically used for highly complex integrated circuits having transistor elements with a gate length around 50 nm or below. A gate electrode 120 may be formed above the semiconductor layer 110. The gate electrode 120 may be formed of doped polysilicon or other suitable material which is provided above the semiconductor layer 110 and is separated therefrom by a gate insulation layer 130. The first semiconductor material 110 forms a channel region 140 for a finished transistor. Sidewalls of the gate electrode 120 are provided with disposable sidewall spacers 150. The disposable sidewall spacers 150 may consist of any appropriate dielectric material, such a silicon nitride, silicon dioxide, or mixtures thereof. The disposable sidewall spacers 150 may be used as an etch and growth mask in an etch process and an epitaxial growth process for the formation of an embedded strained silicon germanium material 160 in a cavity or recess (not shown) previously defined in the semiconductor layer 110. The recess may be formed by performing a well established anisotropic etch process while using the sidewall spacers 150 as a mask. Therefore, the disposable sidewall spacers 150 determine the lateral distance between the sidewalls 165 of the gate electrode 120 and the recess.

It should be appreciated that after the formation of the recess 160, the semiconductor device 100 may be subjected to any necessary or suitable pretreatments for preparing the device 100 for a subsequent epitaxial growth process. Thereafter, the stressed silicon germanium material 160 is grown in the recess. The growth of the stressed silicon germanium material 160 in the recess may performed by using a selective epitaxial growth process using the material of the recess bottom and/or sidewalls as a template. In one illustrative embodiment, an appropriate deposition atmosphere may be established comprising of a silicon-containing precursor material, such as silane, and a germanium-containing precursor material, such as germane. Typically, in selective epitaxial growth processes, the process parameters, such as pressure, temperature, type of carrier gases and the like are selected such that substantially no material is deposited on dielectric surfaces such as the surfaces of the spacer 150 and a possible capping layer (not shown), while a deposition is obtained on exposed surfaces of the first semiconductor layer 110, thereby using this layer as a crystalline template, which substantially determines the crystalline structure of the epitaxially grown stressed silicon germanium material 160. Since the covalent radius of germanium is larger than the covalent radius of the silicon, growing the silicon germanium material on a silicon template results in a strained silicon germanium layer which induces a compressive strain in the channel region 140. In the illustrated embodiment, the percentage of germanium in the silicon germanium material 160 is between about 20-40%. Of course, the percentage may be varied depending on the desired amount of compressive stress.

Doped regions, such as source/drain regions 170 may be formed within the semiconductor layer 110. Extension regions 175, which may include counter-doped halo regions may also be provided for advanced field effect transistors. The particular shape of the doped regions 170, 175 is provided for illustrative purposes only. The dopant profiles may vary depending on the particular transistor requirements. The source and drain regions may be formed by various implantation processes and/or in situ doping during the formation of the silicon germanium material 160.

A silicon carbon layer 180 is formed on a surface region of the silicon germanium material 160. The silicon carbon layer 180 may be formed using various techniques, such as epitaxial growth, or implantation. Appropriate masks may be used for forming the silicon carbon layer 180, if necessitated by the particular formation technique. The usage of the term “silicon carbon” in the silicon carbon layer 180 does not preclude the presence of other components in the layer 180, such as germanium or dopant ions.

In a first technique, the silicon carbon layer 180 is formed by a continuation of the epitaxial growth process used to form the silicon germanium material 160. Without breaking vacuum, a carbon-containing precursor material, such as CH₃Cl, may be added to the silicon-containing precursor material. The germanium-containing precursor material may be reduced in concentration or entirely eliminated during the formation of the silicon carbon layer 180. Hence, the silicon carbon layer 160 may also include germanium at the same concentration or a reduced concentration as compared to the silicon germanium material 160, or the silicon carbon layer 180 may not include germanium. In the illustrated embodiment, the percentage of carbon in the silicon carbon layer 180 is between about 0.5-2%.

In a second technique, an implantation process using a mask (not shown) may be used to introduce carbon in the surface region of the silicon germanium material 160. For example, the same mask pattern used to form the recesses in which the silicon germanium material 160 is formed may be used as the implant mask for forming the silicon carbon layer 180 by implantation. During the implantation a shallow carbon implant energy (e.g., around 1 keV) may be employed with a dose of about 1-5 E15 ions/cm².

As illustrated in FIG. 2, a metal layer 185, such as nickel, cobalt, platinum, titanium, or alloys thereof, is deposited over the semiconductor device 100. The particular metal or alloy may vary depending on the particular implementation. In the case of a nickel based material, pure nickel or a nickel platinum alloy with up to about 10% platinum may be used. In the embodiment shown, the device 100 may be exposed to a thermal treatment for initiating a chemical reaction between material of the metal layer 185 and the surface region including at least the silicon carbon layer 180. The thermal treatment may be performed in accordance with well-established silicidation procedures when a metal silicide is to be formed on the surface region. For example, a rapid thermal anneal (RTA) at a temperature of between about 250-500 degrees C. and a duration of about 5-30 s may be used.

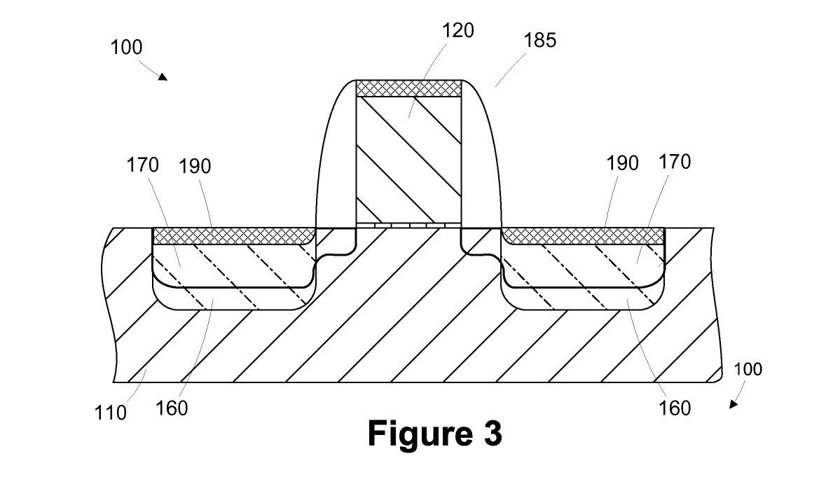

Thus, during the thermal treatment, a substantially uniform diffusion may take place to provide a substantially homogeneous distribution of a metal silicide layer 190, as illustrated in FIG. 3. After the thermal treatment, further processing may be continued, for instance, by a selective etch process to remove any non-reacted material of the metal layer 185, for which well-established wet chemical etch chemistries are available. For example an aqua regia solution may be used for a nickel platinum material. Other selective etch chemistries may be used for different metal compositions. The final depth of the metal silicide layer 190 may be determined by the corresponding process parameters, i.e., the parameters of the thermal treatment in combination with the diffusion characteristics of the materials of the metal layer 185 and the silicon carbon layer 180. In some embodiments, the depth of the silicide layer 190 may be selected so that the silicon carbon layer 180 is consumed. In other embodiments, a portion of the silicon germanium material 160 may also be consumed.

The silicide material may be formed on an upper portion of the gate electrode 120, as shown in FIG. 3. If no silicide is desired on the gate electrode 120, an appropriate capping layer (not shown) may be formed prior to depositing the metal layer 185.

Although the silicide layer 190 is illustrated as being flush with respect to a surface of the substrate 110, it is contemplated that a raised source/drain arrangement may also be used. The silicon carbon layer 180 and/or the silicon germanium material 160 may be formed such that it extends above the surface of the substrate 110 to define a raised region.

Although the doped regions are illustrated as having been previously formed in the semiconductor device 100 prior to forming the metal silicide layer 190, it is contemplated that they could be formed at various points in the process flow, such as after forming the silicon carbon layer 180, at the same time as a carbon implantation process for forming the silicon carbon layer 180, after forming the metal layer 185, after the thermal treatment, etc.

The provision of the carbon in the silicide layer 190 enhances the stability silicide layer 190 as compared to a conventional germano-silicide material and reduces the silicide/silicon germanium interface roughness. Without being bound to a particular theory, it is believed that the carbon out diffuses and collects at the silicide/substrate interface, thereby delaying the nickel diffusion, which leads to a robust silicidation process. Because the silicon carbon layer 180 is consumed in forming the silicide layer 190, there is substantially no relaxation of the silicon germanium material 160. The enhanced silicide thermal stability provides agglomeration at a higher temperature. The improved silicide robustness may provide an increased resistance to attack from an aqua regia solution used to remove the non-reacted metal, thereby allowing the silicide process to be simplified to include one rapid thermal anneal and one wet etch to remove the non-reacted metal. The improved silicide robustness may also provide an increased resistance to the reactive ion etch used for forming contacts that interface with the silicide layer 190.

The techniques described herein may also be applied to semiconductor device features other than transistor contact regions that include silicon germanium layers upon which silicide layers are to be formed.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosed subject matter. Accordingly, the protection sought herein is as set forth in the claims below.

We claim:

1. A method, comprising:
forming a silicon germanium layer;
forming a layer comprising carbon and silicon on a top surface of the silicon germanium layer;
forming a metal layer above the layer comprising carbon and silicon; and
performing a thermal treatment to convert at least the layer comprising carbon and silicon to form a metal silicide layer.

2. The method of claim 1, further comprising converting a portion of the silicon germanium layer beneath the layer comprising carbon and silicon to form the metal silicide layer.

3. The method of claim 1, wherein forming the silicon germanium layer comprises forming the silicon germanium layer using an epitaxial growth process in the presence of silicon and germanium precursors, and forming the layer comprising carbon and silicon by continuing the epitaxial growth process in the presence of a carbon precursor.

4. The method of claim 3, further comprising reducing a concentration of the germanium precursor during the forming of the layer comprising carbon and silicon.

5. The method of claim 3, further comprising performing the epitaxial growth process to forming of the layer comprising carbon and silicon in the absence of a germanium precursor.

6. The method of claim 1, wherein forming the layer comprising carbon and silicon further comprises implanting carbon into the silicon germanium layer.

7. The method of claim 1, wherein forming the metal layer further comprises forming the metal layer comprising nickel.

8. A method, comprising:
forming a gate electrode structure above a semiconductor layer;
forming a recess in the semiconductor layer adjacent the gate electrode;
forming a silicon germanium material in the recess;
forming a layer comprising carbon and silicon on a top surface of the silicon germanium material;
forming a metal layer above the layer comprising carbon and silicon; and
performing a thermal treatment to convert at least the layer comprising carbon and silicon to form a metal silicide layer.

9. The method of claim 8, further comprising converting a portion of the silicon germanium material beneath the layer comprising carbon and silicon to form the metal silicide layer.

10. The method of claim 8, wherein forming the silicon germanium material comprises forming the silicon germanium layer using an epitaxial growth process in the presence of silicon and germanium precursors, and forming the layer comprising carbon and silicon by continuing the epitaxial growth process in the presence of a carbon precursor.

11. The method of claim 10, further comprising reducing a concentration of the germanium precursor during the forming of the layer comprising carbon and silicon.

12. The method of claim 10, further comprising performing the epitaxial growth process to forming of the layer comprising carbon and silicon in the absence of a germanium precursor.

13. The method of claim 8, wherein forming the layer comprising carbon and silicon further comprises implanting carbon into the silicon germanium layer.

14. The method of claim 8, wherein forming the metal layer further comprises forming the metal layer comprising nickel.

15. The method of claim 8, further comprising forming source and drain regions in at least a portion of the silicon germanium material.

16. The method of claim 15, wherein the source and drain regions are formed prior to forming said metal layer.

17. A semiconductor device, comprising:
a silicon germanium layer; and
a silicide layer comprising a metal, silicon, and carbon formed on the silicon germanium layer to define an interface therewith.

18. The device of claim 17, wherein the metal comprises nickel.

19. The device of claim 17, wherein the silicon germanium material is disposed adjacent a gate electrode of a transistor.

20. The device of claim 19, further comprising source and drain regions of the transistor at least partially disposed within the silicon germanium material.
